(19) United States
(12) Patent Application Publication
(10) Pub. No.: US 2013/0335061 A1
(43) Pub. Date: Dec. 19, 2013

(54) Systems and Methods for Monitoring Underground Power Lines

(71) Applicant: GRID20/20, Inc., Richmond, VA (US)

(72) Inventors: Eric George de Buda, Toronto (CA); Randall Turner, Scarborough (CA); John Kuurstra, Mississauga (CA); Young Ngo, Mississauga (CA); Kamran Kholdi-Sabeti, Toronto (CA)

(21) Appl. No.: 13/919,811

(22) Filed: Jun. 17, 2013

Related U.S. Application Data
(60) Provisional application No. 61/660,130, filed on Jun. 15, 2012.

(51) Int. Cl. G01R 21/06

(52) U.S. Cl. CPC G01R 21/06
USPC 324/127

(57) ABSTRACT

A system for monitoring power in accordance with the present disclosure has a transformer monitoring device that interfaces with two electrical conductors electrically connected to a transformer at a location on a power grid and to measure a first current and a second current through the first electrical conductor and the second electrical conductor, respectively. Further, the transformer monitoring device measures a first voltage and a second voltage associated with the first electrical conductor and the second electrical conductor, respectively, and the transformer monitoring device comprises two separate and distinct current measuring devices integral therewith. Additionally, the system comprises logic that calculates values indicative of power corresponding to the transformer based upon the first current and the first voltage and the second current and the second voltage.

### CROSS REFERENCE TO RELATED APPLICATIONS

This application claims priority to U.S. Provisional Application Ser. No. 61/660,130 entitled “Power Monitoring Device and Method,” filed Jun. 15, 2012, which is incorporated herein by reference in its entirety.

### BACKGROUND

Power is generated, transmitted, and distributed to a plurality of endpoints, such as for example, customer or consumer premises (hereinafter referred to as “consumer premises”). Consumer premises may include multiple-family residences (e.g., apartment buildings, retirement homes), single-family residences, office buildings, event complexes (e.g., coliseums or multi-purpose indoor arenas, hotels, sports complexes), shopping complexes, or any other type of building or area to which power is delivered.

The power delivered to the consumer premises is typically generated at a power station. A power station is any type of facility that generates power by converting mechanical power of a generator into electrical power. Energy to operate the generator may be derived from a number of different types of energy sources, including fossil fuels (e.g., coal, oil, natural gas), nuclear, solar, wind, wave, or hydroelectric. Further, the power station typically generates alternating current (AC) power.

The AC power generated at the power station is typically increased (the voltage is “stepped up”) and transmitted via transmission lines typically to one or more transmission substations. The transmission substations are interconnected with a plurality of distribution substations to which the transmission substations transmit the AC power. The distribution substations typically decrease the voltage of the AC power received (the voltage is “stepped down”) and transmit the reduced voltage AC power to distribution transformers that are electrically connected to a plurality of consumer premises. Thus, the reduced voltage AC power is delivered to a plurality of consumer premises. Such a web or network of interconnected power components, transmission lines, and distribution lines is often times referred to as a power grid.

Throughout the power grid, measureable power is generated, transmitted, and distributed. In this regard, at particular midpoints or endpoints throughout the grid, measurements of power received and/or distributed may indicate information related to the power grid. For example, if power distributed at the endpoints on the grid is considerably less than the power received at, for example, distribution transformers, then there may be a system issue that is impeding delivery of power or power may be being diverted through malice. Such power data collection at any of the described points in the power grid and analysis of such data may further aid power suppliers in generating, transmitting, and distributing power to consumer premises.

### BRIEF DESCRIPTION OF THE DRAWINGS

The present disclosure can be better understood with reference to the following drawings. The elements of the drawings are not necessarily to scale relative to each other, emphasis instead being placed upon clearly illustrating the principles of the disclosure. Furthermore, like reference numerals designate corresponding parts throughout the several views.

FIG. 1 is a diagram depicting an exemplary power transmission and distribution system in accordance with an embodiment of the present disclosure.

FIG. 2A is a diagram depicting a transformer and meter power usage data collection system in accordance with an embodiment of the present disclosure.

FIG. 2B is a diagram depicting a line power usage data collection system in accordance with an embodiment of the present disclosure.

FIG. 3 is a perspective view of an underground transformer monitoring device, such as is depicted by FIG. 2A.

FIG. 4 is a block diagram depicting an exemplary operations computing device, such as is depicted in FIG. 2A.

FIG. 5 is a block diagram depicting an exemplary transformer monitoring device, such as is depicted in FIG. 2A.

FIG. 6A is a cut away view of the underground transformer monitor depicted in FIG. 3.

FIG. 6B is a perspective view of a flexible circuit of the underground transformer monitor depicted in FIG. 6A.

FIG. 6C is a perspective view of the flexible circuit and its relation to at least two stiffeners as used in the underground transformer monitor depicted in FIG. 6A.

FIG. 7A is a perspective view of an underground transformer housing in accordance with an embodiment of the present disclosure.

FIG. 7B is an inside view of the underground transformer housing of FIG. 7A and the transformer monitoring device of FIG. 3 in the process of being coupled to the connectors.

FIG. 7C depicts the transformer monitoring device of FIG. 3 coupled to the connectors.

### DETAILED DESCRIPTION

The power transmission and distribution system 100 comprises at least one transmission network 118, at least one distribution network 119, and the consumer premises 106-111 (described hereinabove) interconnected via a plurality of power lines 101a-101j.

In this regard, the power transmission and distribution system 100 is an electric “grid” for delivering electricity generated by a power station 10 to the one or more consumer premises 106-111 via the transmission network 118 and the distribution network 119.

Note that the power lines 101a and 101b are exemplary transmission lines, while power lines 101c, 101d, are exemplary distribution lines. In one embodiment, the transmission lines 101a and 101b transmit electricity at high voltage (110 kV or above) and often via overhead power lines. At distribution transformers, the AC power is transmitted over the distribution lines at lower voltage (e.g., 25 kV or less). Note that in such an embodiment, the power transmission described uses three-phase alternating current (AC). However, other types of power and/or power transmission may be used in other embodiments.

The transmission network 118 comprises one or more transmission substation 102 (only one is shown for simplicity). The power station 10 is electrically coupled to the transmission substation 102 via the power lines 101a, and the transmission substation 102 is electrically connected to the distribution network 119 via the power lines 101b. As described hereinabove, the power station 10 (transformers not shown located at the power station 10) increases the voltage of the power generated prior to transmission over the transmission lines 101a to the transmission substation 102. Note that three wires are shown making up the power lines 101a indicating that the power transmitted to the transmission substation 102 is three-phase AC power. However, other types of power may be transmitted in other embodiments.

In this regard, at the power station 10, electricity is generated, and the voltage level of the generated electricity is “stepped up,” i.e., the voltage of the generated power is increased to high voltage (e.g., 110 kV or greater), to decrease the amount of losses that may occur during transmission of the generated electricity through the transmission network 118.

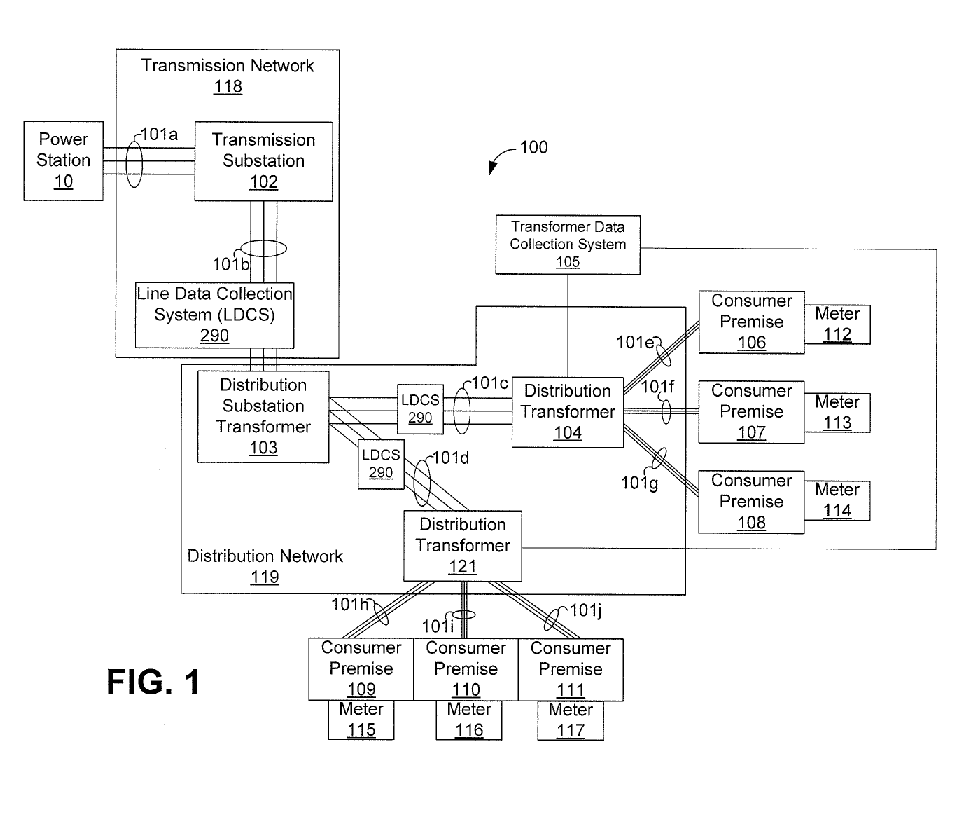

Note that the transmission network 118 depicted in FIG. 1 comprises only two sets of transmission lines 101a and 101b (three lines each for three-phase power transmissions as indicated hereinabove) and one transmission substation 102. The configuration of FIG. 1 is merely an exemplary configuration. The transmission network 118 may comprise additional transmission substations interconnected via a plurality of additional transmission lines. The configuration of the transmission network 118 may depend upon the distance that the voltage-increased electricity may need to travel to reach the desired distribution network 119.

The distribution network 119 transmits electricity from the transmission network 118 to the consumer premises 106-111. In this regard, the distribution network 119 comprises a distribution substation transformer 103 and one or more distribution transformers 104 and 121. Note that the configuration shown in FIG. 1 comprising the distribution substation transformer 103 and two distribution transformers 104 and 121 and showing the distribution substation transformer 103 physically separated from the two distribution transformers 104 and 121 is an exemplary configuration. Other configurations are possible in other embodiments.

As an example, the distribution substation transformer 103 and the distribution transformer 104 may be housed or combined together in other configurations of the distribution network 119 (as well as distribution substation transformer 103 and distribution transformer 121). In addition, one or more transformers may be used to condition the electricity, i.e., transform the voltage of the electricity, to an acceptable voltage level for delivery to the consumer premises 106-111. The distribution substation transformer 103 and the distribution transformer 104 may “step down,” i.e., decrease the voltage of the electricity received from the transmission network 118, before the distribution substation transformer 103 and the distribution transformers 104, 121 transmit the electricity to its intended destinations, e.g., the consumer premises 106-111.

As described hereinabove, in operation the power station 10 is electrically coupled to the transmission substation 102 via the power lines 101a. The power station 10 generates electricity and transmits the generated electricity via the power lines 101a to the transmission substation 102. Prior to transmission, the power station 10 increases the voltage of the electricity so that it may be transmitted over greater distances efficiently without loss that affects the quality of the electricity delivered. As further indicated hereinabove, the voltage of the electricity may need to be increased in order to minimize energy losses as the electricity is being transmitted on the power lines 101b. The transmission substation 102 forwards the electricity to the distribution substation transformer 103 of the distribution network 119.

When the electricity is received, the distribution substation transformer 103 decreases the voltage of the electricity to a range that is useable by the distribution transformers 104, 121. Likewise, the distribution transformers 104, 121 may further decrease the voltage of the electricity received to a range that is useable by the respective electrical systems (not shown) of the consumer premises 106-111.

In one embodiment of the present disclosure, the distribution transformers 104, 121 are electrically coupled to distribution transformer data collection system 105. The distribution transformer data collection system 105 of the present disclosure comprises one or more electrical devices (in one embodiment, the number of devices based upon the number of transformers being monitored) (not shown) that measure operational data via one or more electrical interfaces with the distribution transformers 104, 121. Exemplary operational data includes data related to electricity that is being delivered to or transmitted from the distribution transformers 104, 121, e.g., power measurements, energy measurements, voltage measurements, current measurements, etc. In addition, the distribution transformer data collection system 105 may collect operational data related to the environment in which the distribution transformers 104, 121 are situated, e.g., temperature within the distribution transformers 104, 121.

In accordance with one embodiment of the present disclosure, the distribution transformer data collection system 105 electrically interfaces with power lines 101c, 101d (e.g., a set of three power lines, if the power is three-phase) that are providing electricity to the distribution transformers 104, 121. Thus, the distribution transformer data collection system 105 collects the data, which represents the amount of electricity that is being delivered to the distribution transformers 104, 121. In another embodiment, the distribution transformer data collection system 105 electrically interfaces with the power lines 101e-101j (i.e., the power lines delivering power to the consumer premises 106-111 or any other power lines of the distribution transformer that transmits power down the power grid toward the consumer premises 106-111).

Furthermore, each consumer premise 106-111 comprises an electrical system (not shown) for delivering electricity received from the distribution transformers 104, 121 to one or more electrical ports (not shown) of the consumer premise 106-111. Note that the electrical ports may be internal or external ports.

The electrical system of each consumer premise 106-111 interfaces with a corresponding consumer premise's electrical meter 112-117, respectively. Each electrical meter 112-117 measures the amount of electricity consumed by the consumer premises' electrical system to which it is coupled. In order to charge a customer who is responsible for the consumer premise, a power company (e.g., a utility company or a metering company) retrieves data indicative of the measurements made by the electrical meters 112-117 and uses such measurements to determine the consumer's invoice dollar amount representative of how much electricity has been consumed at the consumer premise 106- 111. Notably, readings taken from the meters 112-117 reflect the actual amount of power consumed by the respective consumer premise electrical system. Thus, in one embodiment of the present disclosure, the meters 112-117 store data indicative of the power consumed by the consumers.

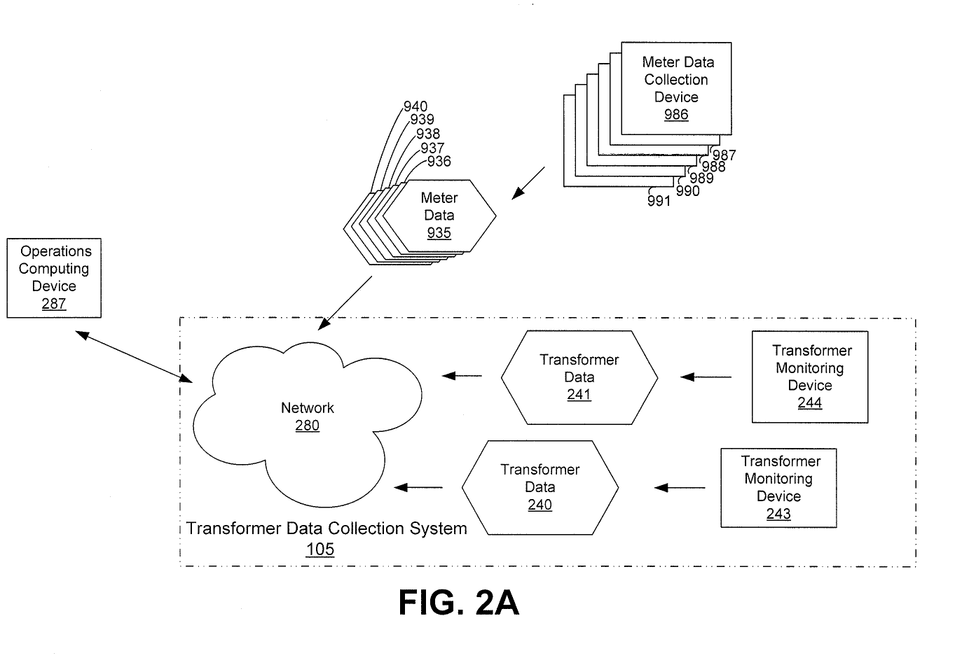

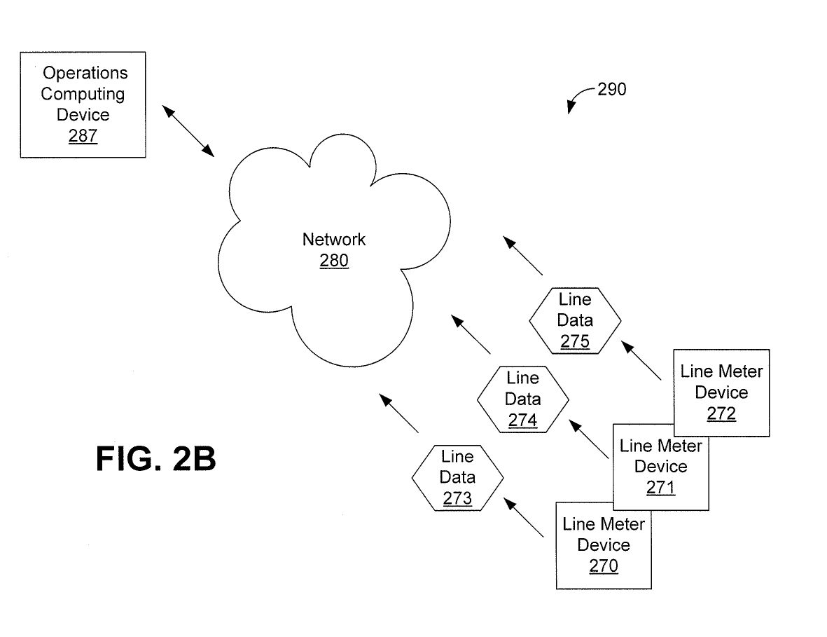

During operation, the meters 112-117 may be queried using any number of methods in order to retrieve and store data indicative of the amount of power being consumed by the meter's respective consumer premise electrical system. In this regard, utility personnel may physically go to the consumer premises 106-111 and read the consumer premise's respective meter 112-117. In such a scenario, the personnel may enter data indicative of the readings into an electronic system, e.g., a hand-held device, a personal computer (PC), or a laptop computer. Periodically, the data entered may be transmitted to an analysis repository. Additionally, meter data retrieval may be electronic and automated. For example, the meters 112-117 may be communicatively coupled to a network (not shown), e.g., a wireless network, and periodically the meters 112-117 may automatically transmit data to a repository, described herein with reference to FIG. 2A.

As will be described further herein, meter data (not shown) (i.e., data indicative of readings taken by the meters 112-117) and transformer data (not shown) (i.e., data indicative of readings taken by the transformer data collection system 105) may be stored, compared, and analyzed in order to determine whether particular events have occurred, for example, whether electricity theft is occurring or has occurred between the distribution transformers 104, 121 and the consumer premises 106-111 or to determine whether power usage trends indicate a need or necessity for additional power supply equipment. In this regard, with respect to the theft analysis, if the amount of electricity being received at the distribution transformers 104, 121 is much greater than the cumulative (or aggregate) total of the electricity that is being delivered to the consumer premises 106-117, then there is a possibility that an offender may be stealing electricity from the utility providing the power.

In one embodiment, the power transmission and distribution system 100 further comprises a line data collection system (LDCS) 290. The LDCS 290 collects line data from the transmission lines 101b-101d. The line data is data indicative of power/electricity measured. Such data may be compared, for example, to meter data (collected at consumer premises 106-111 described further herein) and/or the transformer data (collected at the distribution transformers 104, 121 described further herein) in order to determine losses of electricity along the power grid, electricity usage, power need, or power consumption metrics of the power grid. In one embodiment, data collected may be used to determine whether electricity theft is occurring or has occurred between a transmission substation and a distribution substation or a distribution substation and a distribution transformer (i.e., the distribution transformer that transmits power to the consumer premise). Note that the LDCS 290 is coupled to the transmission lines 101b, 101c, and 101d, respectively, thus coupling to medium voltage (MV) power lines. The LDCS 290 measures and collects operational data, as described hereinabove. In one embodiment, the LDCS may transmit operational data, such as, for example, power, energy, voltage, and/or current, related to the MV power lines 101b, 101c, and 101d.

FIG. 2A depicts the transformer data collection system 105 in accordance with an embodiment of the present disclosure and a plurality of meter data collection devices 986-991. The transformer data collection system 105 comprises one or more transformer monitoring devices 243, 244 (FIG. 1). Note that only two transformer monitoring devices 243, 244 are shown in FIG. 2A but additional transformer monitoring devices may be used in other embodiments, one or a plurality of transformer monitoring devices for each distribution transformer 104, 121 (FIG. 1) being monitored.

Notably, in one embodiment of the present disclosure, the transformer monitoring devices 243, 244 are coupled to secondary side of the distribution transformers, 104, 121 respectively. Thus, measurements taken by the transformer monitoring devices 243, 244 are taken, in effect, at the distribution transformers 104, 121 between the distribution transformers 243, 244 and the consumer premises 106-111 (FIG.

1).

Additionally, the transformer monitoring devices 243, 244, the meter data collection devices 986-991, and an operations computing device 287 may communicate via a network 280. The network 280 may be any type of network over which devices may transmit data, including, but not limited to, a wireless network, a wide area network, a large area network, or any type of network known in the art or future-developed.

In another embodiment, the meter data 935-940 and the transformer data 240, 241, may be transmitted via a direct connection to the operations computing device 287 or manually transferred to the operations computing device 287. As an example, the meter data collection devices 986-991 may be directly connected to the operations computing device 287 via a direction connection, such as for example a T-carrier 1 (T1) line. Also, the meter data 935-940 may be collected on by a portable electronic device (not shown) that is then connected to the operations computing device 287 for transfer of the meter data collected to the operations computing device 287. In addition, meter data 935-940 may be collected manually through visual inspection by utility personnel and provided to the operations computing device 287 in a particular format, e.g., comma separated values (CSV).

Note that in other embodiments of the present disclosure, the meter data collection devices 986-991 may be the meters 112-117 (FIG. 1) themselves, and the meters 112-117 may be equipped with network communication equipment (not shown) and logic (not shown) configured to retrieve readings, store readings, and transmit readings taken by the meters 112-117 to the operations computing device 287.

The transformer monitoring devices 243, 244 are electrically coupled to the distribution transformers 104, 121, respectively. In one embodiment, the devices 243, 244 are electrically coupled to the distribution transformers 104, 121, respectively, on a secondary side of the distribution transformers 104, 121.

The transformer monitoring devices 243, 244 each comprise at least two sensors (not shown) that interface with at least two power lines (not shown) connecting the distribution transformers 104, 121 to the consumer premises 106-111 (FIG. 1). Thus, the one or more sensors of the transformer monitoring devices 243, 244 sense electrical characteristics, e.g., voltage and/or current, present in the power lines as power is delivered to the consumer premises 106-111 through the power lines 101e-101f. Periodically, the transformer monitoring devices 243, 244 sense such electrical characteristics, translate the sensed characteristics into transformer data 240, 241 indicative of electrical characteristics, such as, for example power, and transmit transformer data 240, 241 to the operations computing device 287 via the network 280. Upon receipt, the operations computing device 287 stores the transformer data 240, 241 received.

Note that there is a transformer monitoring device depicted for each distribution transformer in the exemplary system, i.e., transformer monitoring device 243 for monitoring transformer 104 (FIG. 1) and transformer monitoring device 244 for monitoring transformer 121 (FIG. 1). There may be additional transformer monitoring devices for monitoring additional transformers in other embodiments.

The meter data collection devices 986-991 are communicatively coupled to the network 280. During operation, each meter data collection device 986-991 senses electrical characteristics of the electricity, e.g., voltage and/or current, that is transmitted by the distribution transformers 104, 121. Each meter data collection device 986-991 translates the sensed characteristics into meter data 935-940, respectively. The meter data 935-940 is data indicative of electrical characteristics, such as, for example power consumed in addition to specific voltage and/or current measurements. Further, each meter data collection device 986-991 transmits the meter data 935-940, respectively, to the operations computing device 287 via the network 280. Upon receipt, the operations computing device 287 stores the meter data 935-940 received from the meter data collection devices 986-991 indexed (or keyed) with a unique identifier corresponding to the meter data collection device 986-991 that transmits the meter data 935-940.

In one embodiment, each meter data collection device 986-991 may comprise Automatic Meter Reading (AMR) technology, i.e., logic (not shown) and/or hardware, or Automatic Metering Infrastructure (AMI) technology, e.g., logic (not shown) and/or hardware for collecting and transmitting data to a central repository, (or more central repositories,) e.g., the operations computing device 287.

In such an embodiment, the AMR technology and/or AMI technology of each device 986-991 collects data indicative of electricity consumption by its respective consumer premise power system and various other diagnostics information. The meter logic of each meter data collection device 986-991 transmits the data to the operations computing device 287 via the network 280, as described hereinabove. Note that the AMR technology implementation may include hardware such as, for example, handheld devices, mobile devices and network devices based on telephony platforms (wired and wireless), radio frequency (RF), or power line communications (PLC).

Upon receipt, the operations computing device 287 compares aggregate meter data of those meters corresponding to a distribution transformer with the transformer data 240, 241 received from the transformer that provided the transformer data 240, 241.

Thus, assume that meter data collection devices 986-988 are coupled to meters 112-114 (FIG. 1) and transmit meter data 935-937, respectively, and distribution transformer 104 is coupled to transformer monitoring device 243. In such a scenario, the meters 112-114 meter electricity provided by the distribution transformer 104 and consumed by the electrical system of the respective consumer premise 106-108. Therefore, the operations computing device 287 aggregates (e.g., sums) data contained in meter data 935-937 (e.g., power usage recorded by each meter 112-114) and compares the aggregate with the transformer data 240 provided by transformer monitoring device 243.

If the operations computing device 287 determines that the quantity of power that is being delivered to the consumer premises 106-108 connected to the distribution transformer 104 is substantially less than the quantity of power that is being transmitted to the distribution transformer 104, the operations computing device 287 may determine that power (or electricity) theft is occurring between the distribution transformer 104 and the consumer premises 106-108 to which the distribution transformer 104, is connected.

In one embodiment, the operations computing device 287 may store data indicating theft of electricity. In another embodiment, the operations computing device 287 may be monitored by a user (not shown), and the operations computing device 287 may initiate a visual or audible warning that power (or electricity) theft is occurring. This process is described further herein.

In one embodiment, the operations computing device 287 identifies, stores, and analyzes meter data 935-940 based on a particular unique identifier associated with the meter 112-117 to which the meter data collection devices 986-991 are coupled. Further, the operations computing device 287 identifies, stores, and analyzes transformer data 240, 241 based on a unique identifier associated with the distribution transformers 104, 121 that transmitted the transformer data 240, 241 to the operations computing device 287.

Thus, in one embodiment, prior to transmitting data to the operations computing device 287, both the meter data collection devices 986-991 and the transformer monitoring devices 243, 244 are populated internally with a unique identifier (i.e., a unique identifier identifying the meter data collection device 986-991 and a unique identifier identifying the transformer monitoring device 243, 244). Further, each meter data collection device 986-991 may be populated with the unique identifier of the transformer 104, 121 to which the meter data collection device 986-991 is connected.

In such an embodiment, when the meter data collection device 986-991 transmits the meter data 935-940 to the operations computing device 287, the operations computing device 287 can determine which distribution transformer 104 or 121 services the particular consumer premises 106-111. As an example, during setup of a portion of the grid (i.e., power transmission and distribution system 100) that comprises the distribution transformers 104, 121 and the meters 112-117, the operations computing device 287 may receive set up data from the distribution transformers 104, 121 and the meter data collection devices 986-991 identifying the device from which it was sent and a unique identifier identifying the component to which the meter data collection device 986-990 is connected.

FIG. 2B depicts the line data collection system 290 in accordance with an embodiment of the present disclosure. The line data collection system 290 comprises a plurality of line monitoring devices 270-272 and the operations computing device 287. Each line monitoring device 270-272 communicates with the operations computing device 287 via the network 280.

With reference to FIG. 1, the line monitoring devices 270-272 are electrically coupled to the transmission lines 101b, 101c, and 101d, respectively. In one embodiment, each line monitoring device 270-272 comprises one or more sensors (not shown) that interface with the transmission lines 101b, 101c, and 101d connecting the transmission substation 102 downstream to the distribution substation transformer 103 or connecting the distribution substation transformer 103 downstream to the distribution transformers 104, 121.

The one or more sensors of the line monitoring devices 270-272 sense electrical characteristics, e.g., voltage and/or current, present as current flows through transmission lines 101b, 101c, and 101d, respectively. Periodically, each line monitoring device 270-272 senses such electrical characteristics, translates the sensed characteristics into line data 273-275, respectively, indicative of such characteristics, and transmits the line data 273-275 to the operations computing device 287 via the network 280. Upon receipt, the operations computing device 287 stores the line data 273-275 received from the line monitoring devices 270-272.

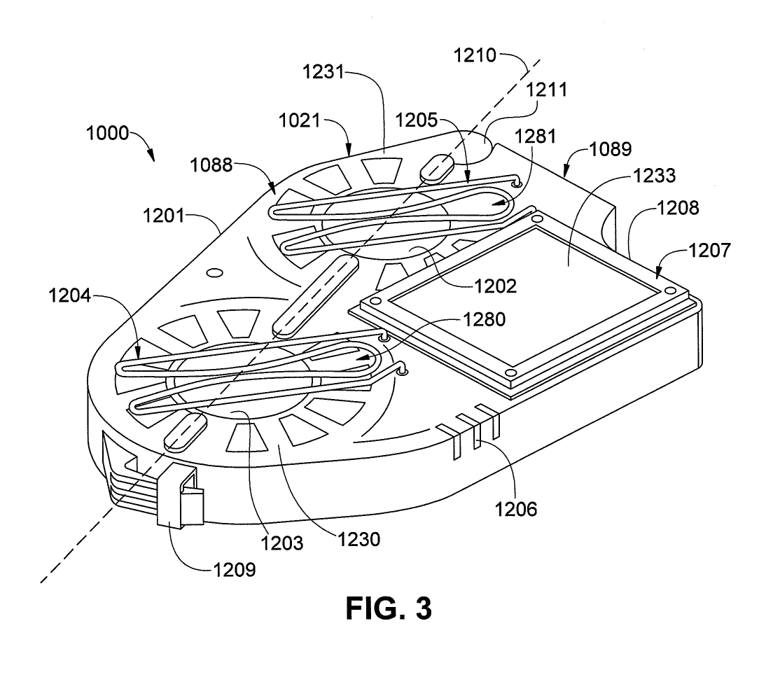

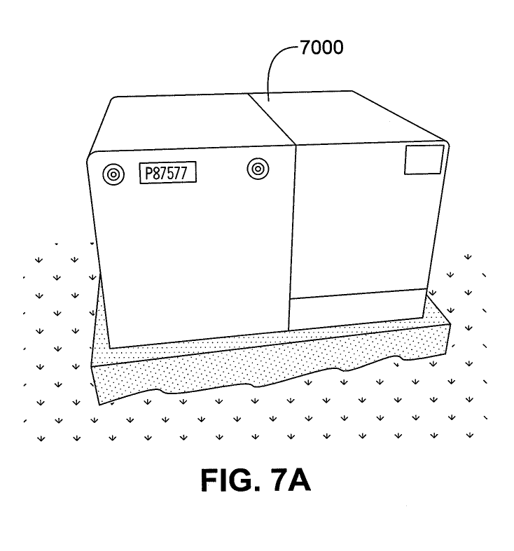

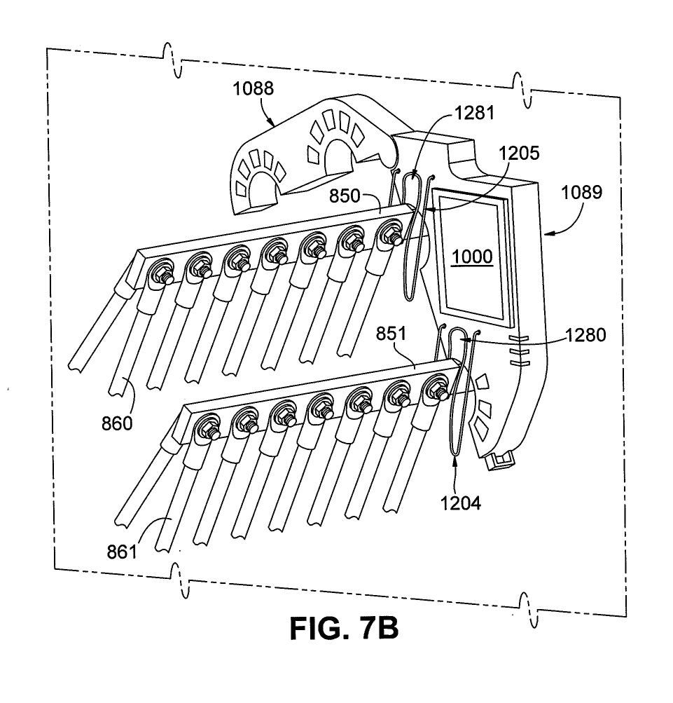

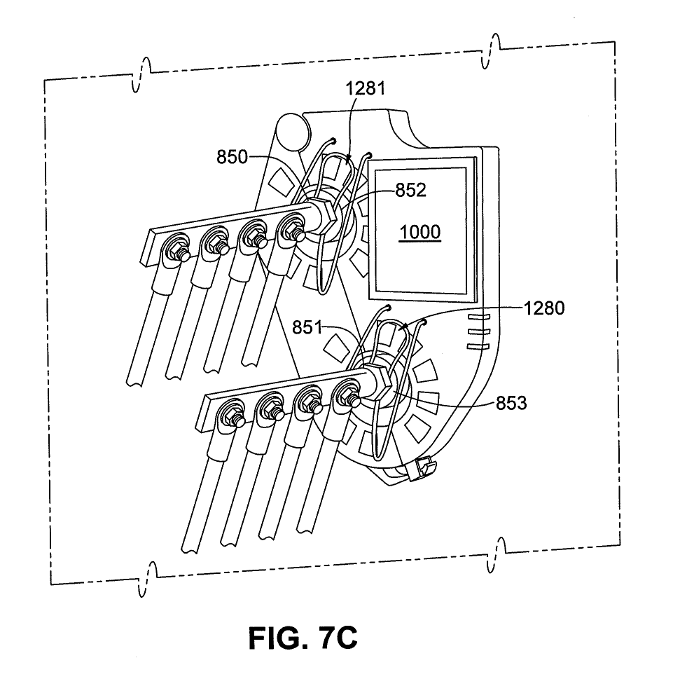

FIG. 3 depicts a perspective view of an embodiment of an underground transformer monitoring device 1000 that may be used as the transformer monitoring devices 243, 244 depicted in FIG. 2A. Note that an underground transformer monitoring device 1000 may be used in what is referred to as a “pad mounted” transformer that is mounted on a concrete pad. An exemplary pad mounted transformer 7000 is shown in the photograph of FIG. 7A.

The transformer monitoring device 1000 may be installed around conductor cables (not shown) or on a conductor cable bus bar (not shown) and used to collect data indicative of power usage from the conductor cables to which it is coupled. Note that a bus bar is a conductive bar that electrically couples to a transformer and comprises a plurality of connectors for receiving one or more conductor cables.

The underground transformer monitoring device 1000 comprises an integral housing 1021. During operation, the housing 1021 is coupled to two conducting cables electronically coupled to a distribution transformer 104, 121.

In this regard, the housing 1021of the underground transformer monitoring device 1000 comprises two sections 1088 and 1089 that are hingedly coupled at hinge 1211. When installed and in a closed position (as shown in FIG. 3), the sections 1088 and 1089 connect together via a latch 1209 and the conductor cables (or bus bar) extend through openings 1202, 1203.

The housing 1021 further comprises a substantially square portion 1207. Within the square portion 1207 resides electronics (e.g., one or more printed circuit boards (PCB), semiconductor chips, and/or other electronics) for performing operations related to the underground transformer monitoring device 1000.

Furthermore, there is an electronic port (not shown) that is covered by a removable cover 1233. Notably, the port electrically couples to the electronics residing in the square portion 1207 and enables additional communication modules to be communicatively coupled to the electronics.

The housing 1021 comprises two sensing unit housings 1230, 1231 that house current detection devices (not shown) for sensing current flowing through their respective conductor cables (or bus bar to which conductor cables are coupled) about which the sections 1088 and 1089 are installed. In one embodiment, the current detection device comprises an implementation of one or more Ragowski coils as described in U.S. Pat. No. 7,940,039 ('039 Patent), which is incorporated herein by reference. Such current detection devices are electrically coupled to the electronics, i.e., directly or indirectly via passive conductive elements.

Additionally, the housing 1021 comprises clips 1204, 1205 made of a conductive material (e.g., a conductive metal). The clips 1204, 1205 are coupled to the housing 1021 and extend across the openings 1203, 1202, respectively. Further, the clips 1204 and 1205 are configured such that each has a slotted opening 1280 and 1280.

When the sections 1088 and 1089 are coupled around a bus bar, the bus bar is inserted into the slotted openings 1280, 1281. When the clips 1204, 1205 conductively contact the bus bar, the clips 1204, 1205 exhibit (i.e., passively sense) a voltage at the bus bar indicative of the voltage exhibited by the conductor cables. In this regard, the clips 1204, 1205 are electrically coupled to the electronics, i.e., directly or indirectly via passive conductive elements.

Further, the clips 1204, 1205 are conductively coupled to a power source (not shown). In this regard, via the clips 1204 and 1205 power may be supplied to the underground transformer monitoring device 1000. Note that the power source may be contained in a housing (not shown) that also houses the transformer (not shown). In this regard, FIG. 7A depicts a underground transformer housing 7000 comprising a first portion that can be opened so that cables and connectors are accessible and a second portion that is not readily accessible that houses the transformer. The power source may be located within the second portion that houses the transformer or in the first portion that houses the cables and connectors.

The housing 1021 is configured such that the underground transformer monitoring device 1000 can be easily installed on the conductor cables or the bus bar. In this regard, the housing 1021 comprises an elongated arc 1208 designed to avoid interference with other structures on the power system on which the underground transformer monitoring device 1000 is being installed.

During operation, the electronics residing in the square portion 1207 collect data indicative of current through the conductor cables or the bus bar and voltage at connectors coupling the conductor cables to the distribution transformers 104, 112. The data indicative of the current and voltage sensed corresponding to the respective conductors is used to calculate power usage.

Note that the underground transformer monitoring device 1000 may be used to collect data from a three phase system (if multiple general purpose transformer monitoring devices 100 are used) or a single phase system. With respect to a single phase system, the single phase system has two conductor cables and a neutral cable. For example, electricity supplied to a typical home in the United States has two conductor cables (or hot cables) and a neutral cable. Note that the voltage across the conductor cables in such an example is 240 Volts (the total voltage supplied) and the voltage across one of the conductor cables and the neutral is 120 Volts. Such an example is typically viewed as a single phase system.

In a three phase system, there are typically three conductor cables and a neutral cable. The voltage in each conductor cable is 120° out of phase the voltage in the other conductor cables. Multiple underground transformer monitoring devices 1000 can obtain current readings from each conductor cable and voltage readings between each of the conductor cables and the neutral (or obtain voltage readings between each of the conductor cables).

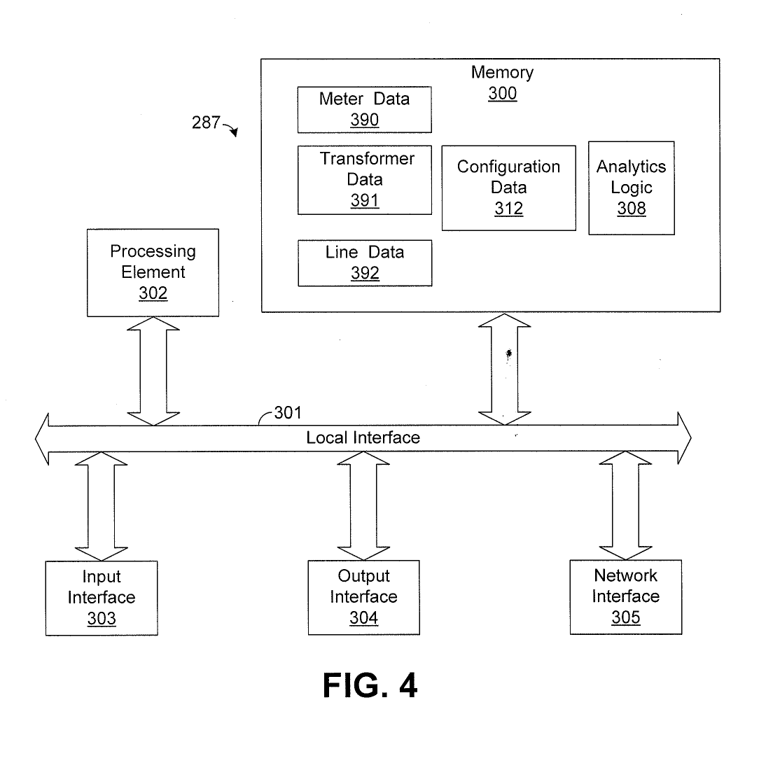

The housing 1021 of the underground transformer monitoring device 1000 further comprises one or more light emitting diodes (LEDs) 1206. The LEDs may be used by logic (not shown referred to herein with reference to FIG. 4 as analytics logic 308) to indicate status, operations, or other functions performed by the general purpose transformer monitoring device 1000.

FIG. 4 depicts an exemplary embodiment of the operations computing device 287 depicted in FIG. 2A. As shown by FIG. 4, the operations computing device 287 comprises analytics logic 308, meter data 390, transformer data 391, line data 392, and configuration data 312 all stored in memory 300.

The analytics logic 308 generally controls the functionality of the operations computing device 287, as will be described in more detail hereafter. It should be noted that the analytics logic 308 can be implemented in software, hardware, firmware or any combination thereof. In an exemplary embodiment illustrated in FIG. 4, the analytics logic 308 is implemented in software and stored in memory 300.

Note that the analytics logic 308, when implemented in software, can be stored and transported on any computer-readable medium for use by or in connection with an instruction execution apparatus that can fetch and execute instructions. In the context of this document, a “computer-readable medium” can be any means that can contain or store a computer program for use by or in connection with an instruction execution apparatus.

The exemplary embodiment of the operations computing device 287 depicted by FIG. 4 comprises at least one conventional processing element 302, such as a digital signal processor (DSP) or a central processing unit (CPU), that communicates to and drives the other elements within the operations computing device 287 via a local interface 301, which can include at least one bus. Further, the processing element 302 is configured to execute instructions of software, such as the analytics logic 308.

An input interface 303, for example, a keyboard, keypad, or mouse, can be used to input data from a user of the operations computing device 287, and an output interface 304, for example, a printer or display screen (e.g., a liquid crystal display (LCD)), can be used to output data to the user. In addition, a network interface 305, such as a modem, enables the operations computing device 287 to communicate via the network 280 (FIG. 2A) to other devices in communication with the network 280.

As indicated hereinabove, the meter data 390, the transformer data 391, the line data 392, and the configuration data 312 are stored in memory 300. The meter data 390 is data indicative of power usage measurements and/or other electrical characteristics obtained from each of the meters 112-117 (FIG. 1). In this regard, the meter data 390 is an aggregate representation of the meter data 935-940 (FIG. 2A) received from the meter data collection devices 986-991 (FIG. 2A).

In one embodiment, the analytics logic 308 receives the meter data 935-940 and stores the meter data 935-940 (as meter data 390) such that the meter data 935-940 may be retrieved based upon the transformer 104 or 121 (FIG. 1) to which the meter data's corresponding meter 112-117 is coupled. Note that meter data 390 is dynamic and is collected periodically by the meter data collection devices 986-991 from the meters 112-117. For example, the meter data 390 may include, but is not limited to, data indicative of current measurements, voltage measurements, and/or power calculations over a period of time per meter 112-117 and/or per transformer 104 or 121. The analytics logic 308 may use the collected meter data 390 to determine whether the amount of electricity supplied by the corresponding transformer 104 or 121 is substantially equal to the electricity that is received at the consumer premises 106-111.

In one embodiment, each entry of the meter data 935-940 in the meter data 390 is associated with an identifier (not shown) identifying the meter 112-117 (FIG. 1) from which the meter data 935-940 is collected. Such identifier may be randomly generated at the meter 112-117 via logic (not shown) executed on the meter 112-117.

In such a scenario, data indicative of the identifier generated by the logic at the meter 112-117 may be communicated, or otherwise transmitted, to the transformer monitoring device 243 or 244 to which the meter is coupled. Thus, when the transformer monitoring devices 243, 244 transmit transformer data 240, 241, each transformer monitoring device 243, 244 can also transmit its unique meter identifier (and/or the unique identifier of the meter that sent the transformer monitoring device 243, 244 the meter data). Upon receipt, the analytics logic 308 may store the received transformer data 240, 241 (as transformer data 391) and the unique identifier of the transformer monitoring device 243, 244 and/or the meter unique identifier such that the transformer data 391 may be searched on the unique identifiers when performing calculations. In addition, the analytics logic 308 may store the unique identifiers of the transformer monitoring devices 243, 244 corresponding to the unique identifiers of the meters 112-117 from which the corresponding transformer monitoring devices 243, 244 receive meter data. Thus, the analytics logic 308 can use the configuration data 312 when performing operations, such as aggregating particular meter data entries in meter data 390 to compare to transformer data 391.

The transformer data 391 is data indicative of aggregated power usage measurements obtained from the distribution transformers 104, 121. Such data is dynamic and is collected periodically. Note that the transformer data 240, 241 comprises data indicative of current measurements, voltage measurements, and/or power calculations over a period of time that indicates the amount of aggregate power provided to the consumer premises 106-111. Notably, the transformer data 391 comprises data indicative of the aggregate power that is being sent to a “group,” i.e., two or more consumer premises being monitored by the transformer monitoring devices 243, 244, although the transformer data 391 can comprise power data that is being sent to only one consumer premises being monitoried by the transformer monitoring device.

In one embodiment, during setup of a distribution network 119 (FIG. 1), the analytics logic 308 may receive data identifying the unique identifier for one or more transformers 104, 121. In addition, when a transformer monitoring device 243, 244 is installed and electrically coupled to one or more transformers 104, 121, data indicative of the unique identifier of the transformers 104, 121 may be provided to the meters 112-117 and/or to the operations computing device 287, as described hereinabove. The operations computing device 287 may store the unique identifiers (i.e., the unique identifier for the transformers) in configuration data 312 such that each meter 112-117 is correlated in memory with a unique identifier identifying the distribution transformer from which the consumer premises 106-111 associated with the meter 112-117 receives power.

The line data 273-275 is data indicative of power usage measurements obtained from the line data collection system 290 along transmission lines 101b-101d in the system 100. Such data is dynamic and is collected periodically. Note that the line data 273-274 comprises data indicative of current measurements, voltage measurements, and/or power calculations over a period of time that indicates the amount of aggregate power provided to the distribution substation transformer 103 and the distribution transformers 104, 121. Notably, the line data 392 comprises data indicative of the aggregate power that is being sent to a “group,” i.e., one or more distribution substation transformers 103.

During operation, the analytics logic 308 receives meter data 935-940 via the network interface 305 from the network 280 (FIG. 2) and stores the meter data 935-940 as meter data 390 in memory 300. The meter data 390 is stored such that it may be retrieved corresponding to the distribution transformer 104, 121 supplying the consumer premise 106-111 to which the meter data corresponds. Note there are various methods that may be employed for storing such data including using unique identifiers, as described hereinabove, or configuration data 312, also described hereinabove.

The analytics logic 308 may perform a variety of functions to further analyze the power transmission and distribution system 100 (FIG. 1). As an example, and as discussed hereinabove, the analytics logic 308 may use the collected transformer data 391, line data 392, and/or meter data 390 to determine whether electricity theft is occurring along the transmission lines 101a, 101b or the distribution lines 101c-101j. In this regard, the analytics logic 308 may compare the aggregate power consumed by the group of consumer premises (e.g., consumer premises 106-108 or 109-111) and compare the calculated aggregate with the actual power supplied by the corresponding distribution transformer 104 or 121. In addition, the analytics logic 308 may compare the power transmitted to the distribution substation transformer 103 and the aggregate power received by the distribution transformers 104, 121, or the analytics logic 308 may compare the power transmitted to the transmission substation 102 and the aggregate power received by one or more distribution substation transformers 103.

If comparisons indicate that electricity theft is occurring anywhere in the power and distribution system 100, the analytics logic 308 may notify a user of the operations computing device 287 that there may be a problem. In addition, the analytics logic 308 can pinpoint a location in the power transmission and distribution system 100 where theft may be occurring. In this regard, the analytics logic 308 may have a visual or audible alert to the user, which can include a map of the system 100 and a visual identifier locating the problem.

As indicated hereinabove, the analytics logic 308 may perform a variety of operations and analysis based upon the data received. As an example, the analytics logic 308 may perform a system capacity contribution analysis. In this regard, the analytics logic 308 may determine when one or more of the consumer premises 106-111 have coincident peak power usage (and/or requirements). The analytics logic 308 determines, based upon this data, priorities associated with the plurality of consumer premises 106-111, e.g. what consumer premises requires a particular peak load and at what time. Loads required by the consumer premises 106-111 may necessarily affect system capacity charges; thus, the priority may be used to determine which consumer premises 106-111 may benefit from demand management.

Additionally, the analytics logic 308 may use the meter data 390 (FIG. 4), the transformer data 391, the line data 392, and the configuration data 312 (collectively referred to as “operations computing device data”) to determine asset loading. For example, analyses may be performed for substation and feeder loading, transformer loading, feeder section loading, line section loading, and cable loading. Also, the operations computing device data may be used to produce detailed voltage calculations and analysis of the system 100 and/or technical loss calculations for the components of the system 100, and to compare voltages experienced at each distribution transformer with the distribution transformer manufacturer minimum/maximum voltage ratings and identify such distribution transformer(s) which are operating outside of the manufacturer's suggested voltages range thereby helping to isolate power sag and power swell instances, and identify distribution transformer sizing and longevity information.

In one embodiment, a utility company may install load control devices (not shown). In such an embodiment, the analytics logic 308 may use the operations computing device data to identify one or more locations of load control devices.

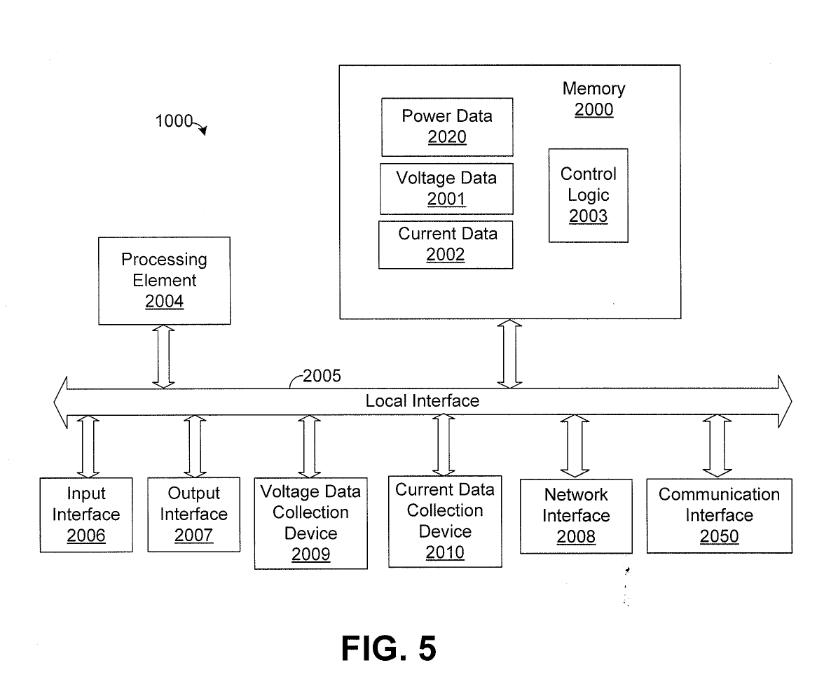

FIG. 5 depicts an exemplary embodiment of the transformer monitoring device 1000 depicted in FIG. 3. As shown by FIG. 5, the transformer monitoring device 1000 comprises control logic 2003, voltage data 2001, current data 2002, and power data 2020 stored in memory 2000.

The control logic 2003 controls the functionality of the operations transformer monitoring device 1000, as will be described in more detail hereafter. It should be noted that the control logic 2003 can be implemented in software, hardware, firmware or any combination thereof. In an exemplary embodiment illustrated in FIG. 5, the control logic 2003 is implemented in software and stored in memory 2000.

Note that the control logic 2003, when implemented in software, can be stored and transported on any computer-readable medium for use by or in connection with an instruction execution apparatus that can fetch and execute instructions. In the context of this document, a “computer-readable medium” can be any means that can contain or store a computer program for use by or in connection with an instruction execution apparatus.

The exemplary embodiment of the transformer monitoring device 1000 depicted by FIG. 5 comprises at least one conventional processing element 2004, such as a digital signal processor (DSP) or a central processing unit (CPU), that communicates to and drives the other elements within the transformer monitoring device 1000 via a local interface 2005, which can include at least one bus. Further, the processing element 2004 is configured to execute instructions of software, such as the control logic 2003.

An input interface 2006, for example, a keyboard, keypad, or mouse, can be used to input data from a user of the transformer monitoring device 1000, and an output interface 2007, for example, a printer or display screen (e.g., a liquid crystal display (LCD)), can be used to output data to the user. In addition, a network interface 2008, such as a modem or wireless transceiver, enables the transformer monitoring device 1000 to communicate with the network 280 (FIG. 2A).

In one embodiment, the transformer monitoring device 1000 further comprises a communication interface 2050. The communication interface 2050 is any type of interface that when accessed enables power data 2020, voltage data 2001, current data 2002, or any other data collected or calculated by the transformer monitoring device 100 to be communicated to another system or device. As an example, the communication interface may be a serial bus interface that enables a device that communicates serially to retrieve the identified data from the transformer monitoring device 1000. As another example, the communication interface 2050 may be a universal serial bus (USB) that enables a device configured for USB communication to retrieve the identified data from the transformer monitoring device 1000. Other communication interfaces 2050 may use other methods and/or devices for communication including radio frequency (RF) communication, cellular communication, power line communication, and WiFi communications. The transformer monitoring device 1000 further comprises one or more voltage data collection devices 2009 and one or more current data collection devices 2010. In this regard, with respect to the transformer monitoring device 1000 depicted in FIG. 3, the transformer monitoring device 1000 comprises the voltage data collection device 2009 that may include the cables 1004, 1007 (FIG. 3) that sense voltages at nodes (not shown) on a transformer to which the cables are attached. As will be described further herein, the control logic 2003 receives data via the cables 1004, 1007 indicative of the voltages at the nodes and stores the data as voltage data 2001. The control logic 2003 performs operations on and with the voltage data 2001, including periodically transmitting the voltage data 2001 to, for example, the operations computing device 287 (FIG. 2A).

Further, with respect to the transformer monitoring device 1000 depicted in FIG. 3, the transformer monitoring device 1000 comprises the current sensors (not shown) contained in the sensing unit housing 1005 (FIG. 3) and the sensing unit housing section 1018 (FIG. 3), which are described hereinabove. The current sensors sense current traveling through conductor cables (or neutral cables) around which the sensing unit housings 1005, 1018 are coupled. As will be described further herein, the control logic 2003 receives data indicative of current from the satellite sensing unit 1021 (FIG. 3) via the cable 1011 and data indicative of the current from the current sensor of the main unit 1001 contained in the sensing unit housing section 1018. The control logic 2003 stores the data indicative of the currents sensed as the current data 2002. The control logic 2003 performs operations on and with the current data 2002, including periodically transmitting the voltage data 2001 to, for example, the operations computing device 287 (FIG. 2A).

Note that the control logic 2003 may perform calculations with the voltage data 2001 and the current data 2002 prior to transmitting the voltage data 2001 and the current data 2002 to the operations computing device 287. In this regard, for example, the control logic 2003 may calculate power usage using the voltage data 2001 and current data 2002 over time and periodically store resulting values as power data 2020.

During operations, the control logic 2003 may transmit data to the operations computing device 287 via the cables via a power line communication (PLC) method. In other embodiments, the control logic 2003 may transmit the data via the network 280 (FIG. 2A) wirelessly or otherwise.

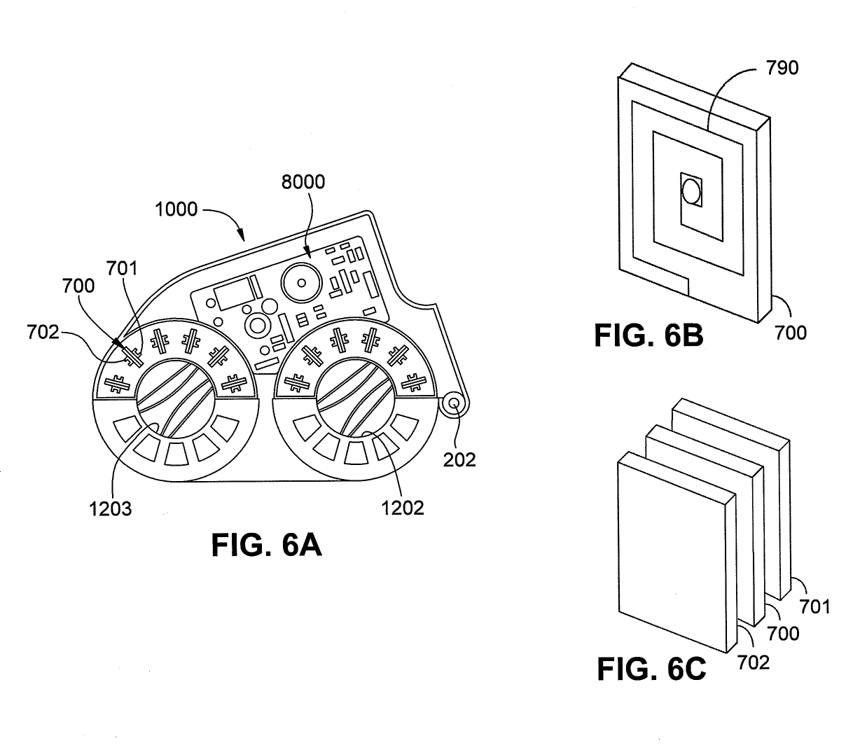

FIGS. 6A depicts a cut away view of the underground transformer monitoring device 1000. FIG. 6A shows the housings 1230 and 1231 housing a plurality of flexible circuits 700 extending radially from the openings 1202 and 1203. The flexible circuits 700 are sandwiched between stiffeners 701 and 702, which protect the flexible circuits 700 and hold them in place.

Further, FIG. 6A shows exemplary electronics 8000 described hereinabove. The electronics 8000 electrically interface with the flexible circuits 800 and the clips 1204 and 1205 so that current and voltage data can be collected.

FIG. 6B depicts an exemplary flexible circuit 700. The flexible circuit 700 comprises printed circuit board (PCB) coils, which are described further in the '039 patent, which is incorporated by reference. Notably, the PCB coils sense the current flowing through the conductor cables or the bus bar.

FIG. 6C depicts the flexible circuit 700 and the stiffeners 701 and 702. Each of the plurality of flexible circuits 700 are sandwiched between stiffeners 701 and 702.

FIGS. 7A-7C depict use and operation of the exemplary underground transformer monitoring device 1000 shown in the photograph in FIG. 3. In this regard, FIG. 7A is a depicts the exemplary underground transformer housing 7000, which houses a transformer (not shown) that is often referred to as a “pad mounted” transformer. One or more cables (not shown) carry electricity from the transformer contained in the housing 7000 to a destination (not shown), e.g., consumer premises 106-111 (FIG. 1).

FIG. 7B depicts the exemplary inside of the housing 7000 showing the exemplary underground transformer monitoring device 1000 in the process of being coupled to bus bars 850 and 851. In this regard, the portion of the housing 7000 shown is in an open position, i.e., such that technicians can access the various cables and connectors within the housing. The portion shown in FIG. 7B houses cables and connectors and the portion not shown in FIG. 7B houses the transformer.

A plurality of cables 860, 861 deliver electricity to the destination, e.g., consumer premises 106-111, from the transformer. In the embodiment shown in FIG. 7B, the plurality of cables 860, 861 are conductively coupled to respective bus bars 850, 851. The bus bars 850, 851 are electrically connected to the transformer.

As described hereinabove, the bus bars 850, 851 couple to a plurality of conductor cables 860, 861. Note that the cables 860, 861 may be neutral cables as well, and measurements may be taken across a conductor cable and a neutral cable or two conductor cables.

In coupling the underground transformer monitoring device 1000 to the transformer, the clips 1204, 1205 are slid (by the technician) over the bus bars 850, 851, such that the bus bars 850, 851 are positioned in the slotted openings 1281, 1280, respectively. Thus, electrical contact is made between clips 1204, 1205 and the bus bars 851, 850, respectively.

FIG. 7C depicts the exemplary underground transformer monitoring device 1000 coupled to bus bars 850 and 851. In this regard, the sections 1088 and 1089 have been hingedly closed together and the latch 1209 has been latched. The openings 1203 and 1202 are positioned about the bus bars 850 and 851, and the bus bars 850 and 851 are inserted in the slotted openings 1280 and 1281.

What is claimed is:

1. A system for monitoring power, comprising:
a transformer monitoring device configured to interface with two electrical conductors electrically connected to a transformer at a location on a power grid and to measure a first current and a second current through the first electrical conductor and the second electrical conductor, respectively, the transformer monitoring device further configured to measure a first voltage and a second voltage associated with the first electrical conductor and the second electrical conductor, respectively, wherein the transformer monitoring device comprises two separate and distinct current measuring devices integral therewith ;
logic configured to calculate values indicative of power corresponding to the transformer based upon the first current and the first voltage and the second current and the second voltage.

2. The system for monitoring power of claim 1, wherein the transformer monitoring device comprises a communication interface for interfacing with a device configured to retrieve data indicative of the power value, the first current, the first voltage, the second current, or the second voltage.

3. The system for monitoring power of claim 1, further comprising an operations computing device.

4. The system for monitoring power of claim 3, wherein the transformer monitoring devices comprise a network interface for interfacing with a network communicatively coupled to the operations computing device.

5. The system for monitoring power of claim 4, wherein transformer monitoring device is configured to transmit data indicative of the power values to the operations computing device.

6. The system for monitoring power of claim 5, wherein the transformer monitoring devices are configured to transmit data indicative of the first current, the first voltage, the second current, and the second voltage to the operations computing device.

7. The system for monitoring power of claim 6, wherein the operations computing device is configured to receive data from a monitoring device electrically coupled to a second location on the power grid, the data indicative of electrical measurements of the second location.

8. The system for monitoring power of claim 7, wherein the operations computing device is configured to compare the data indicative of the electrical measurements from the second location to the data indicative data indicative of the power values, the first current, the first voltage, the second current, and the second voltage.

9. A method for monitoring power, comprising:
electrically interfacing a transformer monitoring device configured with two electrical conductors electrically connected to a transformer at a location on a power grid;
measuring a first current and a second current through the first electrical conductor and the second electrical conductor, respectively;
measuring a first voltage and a second voltage associated with the first electrical conductor and the second electrical conductor, respectively, wherein the transformer monitoring device comprises two separate and distinct current measuring devices integral therewith ;
calculating values indicative of power corresponding to the transformer based upon the first current and the first voltage and the second current and the second voltage.

10. The method for monitoring power of claim 9, further comprising:
communicatively interfacing a data retrieval device to the transformer monitoring device; and
retrieving data indicative of the power values, the first current, the first voltage, the second current, or the second voltage.

11. The method for monitoring power of claim 10, further comprising communicatively interfacing with a network that is communicatively coupled to an operations computing device.

12. The method for monitoring power of claim 11, further comprising transmitting data indicative of the power values to the operations computing device.

13. The method for monitoring power of claim 11, further comprising transmitting data indicative of the first current, the first voltage, the second current, and the second voltage to the operations computing device.

14. The method for monitoring power of claim 13, further comprising receiving, by the operations computing device, data from a monitoring device electrically coupled to a second location on the power grid, the data indicative of electrical measurements of the second location.

15. The method for monitoring power of claim 14, further comprising comparing the data indicative of the electrical measurements from the second location to the data indicative of the power values, the first current, the first voltage, the second current, and the second voltage.
